(19) United States
(12) Patent Application Publication
(10) Pub. No.: US 2025/0293105 A1
(43) Pub. Date: Sep. 18, 2025

(54) METHOD FOR MANUFACTURING SEMICONDUCTOR PACKAGE

(71) Applicant: Resonac Corporation, Minato-ku, Tokyo (JP)

(72) Inventors: Yuki IMAZU, Minato-ku, Tokyo (JP); Keiichi HATAKEYAMA, Minato-ku, Tokyo (JP); Motoo AOYAMA, Minato-ku, Tokyo (JP); Dongchul KANG, Minato-ku, Tokyo (JP); Sadaaki KATO, Minato-ku, Tokyo (JP); Keiko UENO, Minato-ku, Tokyo (JP); Kazue HIRANO, Minato-ku, Tokyo (JP); Hiroaki MATSUBARA, Minato-ku, Tokyo (JP); Kei ITAGAKI, Minato-ku, Tokyo (JP); Masaya TOBA, Minato-ku, Tokyo (JP)

(21) Appl. No.: 18/859,166

(22) PCT Filed: Aug. 31, 2023
(86) PCT No.: PCT/JP2023/032021

§ 371 Date: Oct. 23, 2024

(30) Foreign Application Priority Data
Sep. 2, 2022 (WO) PCT/JP2022/033144

(51) Int. Cl. H01L 23/14; H01L 23/10; H01L 23/29; H01L 23/498

(52) U.S. Cl. CPC H01L 23/145; H01L 23/10; H01L 23/295; H01L 23/49816; H01L 23/49838

(57) ABSTRACT

A method for manufacturing a semiconductor package, including preparing an intermediate structure including a base material and a redistribution layer, the base material having a first main surface and a second main surface on a rear side of the first main surface, the redistribution layer being provided on the first main surface and having an insulating resin layer and wiring, the base material having a resin portion including a through portion that penetrates from the first main surface to the second main surface, the redistribution layer forming a trench having a bottom surface on which the through portion is exposed; and cutting the through portion along the trench, thereby forming a plurality of wiring structures, each having the divided base material.

### TECHNICAL FIELD

The present disclosure relates to a method for manufacturing a semiconductor package.

### BACKGROUND ART

An exemplary semiconductor package with a plurality of semiconductor components arranged two-dimensionally is a so-called 2.3-dimensional type, which features an interposer with fine wiring for connecting the multiple semiconductor components (e.g., Patent Literatures 1 and 2).

### CITATION LIST

### Patent Literature

Patent Literature 1: U.S. Patent Application Publication No. 2021/0074646
Patent Literature 2: U.S. Patent Application Publication No. 2021/0074645

### SUMMARY OF INVENTION

### Technical Problem

In a method for manufacturing an electronic component device that has an insulating resin layer and a wiring layer including wiring, multiple wiring structures may be formed from a single intermediate structure on which a wiring layer is formed by cutting a base material, which includes a resin portion, along with the wiring layer. However, since it is typical that the insulating resin layer constituting the wiring layer and the resin portion constituting the base material have different physical properties like hardness, cutting both at the same time using the same method is likely to cause a defect such as damage to one of them. This is particularly challenging when the base material includes a relatively hard resin portion that contains a lot of inorganic filler, as a cutting method suitable for cutting the resin portion is liable to cause delamination or damage to the insulating resin layer that constitutes the wiring layer.

### Solution to Problem

The present disclosure includes the following.

[1]

A method for manufacturing a semiconductor package, comprising:
preparing an intermediate structure including a base material and a redistribution layer, the base material having a first main surface and a second main surface on a rear side of the first main surface, the redistribution layer being provided on the first main surface and comprising an insulating resin layer and wiring provided in the insulating resin layer, the base material comprising a resin portion comprising a through portion penetrating from the first main surface to the second main surface, the redistribution layer forming a trench having a bottom surface on which the through portion is exposed;
cutting the through portion along the trench, thereby forming a plurality of wiring structures, each comprising the divided base material and the redistribution layer provided on the base material,
in which the base material comprises
a first sealing structure comprising a first sealing resin layer with the first main surface and a rear surface on a rear side of the first main surface and a plurality of first semiconductor components sealed by the first sealing resin layer and connected to the wiring of the redistribution layer;
a second sealing structure comprising a second sealing resin layer having the second main surface and a rear surface on a rear side of the second main surface, a buildup layer being in contact with the rear surface, a plurality of second semiconductor components sealed by the second sealing resin layer on the buildup layer, and a plurality of connection terminals provided on a side of the buildup layer opposite to the second sealing resin layer; and
an underfill layer, and
the buildup layer forms an internal trench having a bottom surface on which the second sealing resin layer is exposed,
the second sealing structure is arranged so that a gap is formed between the first sealing structure and the second sealing structure in an orientation in which the connection terminal is in contact with the first sealing structure, and the first sealing structure and the second sealing structure are arranged so that the bottom surface of the trench and the bottom surface of the internal trench overlap when viewed from a thickness direction of the base material,
the underfill layer fills a periphery of the connection terminal in the gap and the internal trench,
the resin portion comprises the first sealing resin layer, the underfill layer, and the second sealing resin layer,
the through portion is cut along the trench and the internal trench, and
each of the plurality of wiring structures being formed has one or more of the first semiconductor components and one or more of the second semiconductor components.
   [2]

The method according to [1], in which the resin portion comprises an inorganic filler.

[3]

The method according to [2], in which
the insulating resin layer does not comprise an inorganic filler, or the insulating resin layer comprises the inorganic filler, and
in a case where the insulating resin layer comprises the inorganic filler, the ratio of the volume of the inorganic filler comprised in the insulating resin layer to the volume of the insulating resin layer is smaller than the ratio of the volume of the inorganic filler comprised in the resin portion to the volume of the resin portion.
   [4]

The method according to any one of [1] to [3], in which the intermediate structure is prepared in a way that includes forming the redistribution layer forming the trench on the base material.

[5]

The method according to any one of [1] to [4], in which
the intermediate structure is prepared in a way that includes
forming the redistribution layer forming the trench on the first sealing structure,
arranging the second sealing structure on the side of the first sealing structure opposite to the redistribution layer in the orientation in which the connection terminal is in contact with the second sealing structure so that a gap is formed between the first sealing structure and the second sealing structure and so that the bottom surface of the trench overlaps with the bottom surface of the internal trench when viewed in the thickness direction of the base material; and
forming an underfill layer that fills the periphery of the connection terminal in the gap and fills the internal trench.
   [6]

The method according to any one of [1] to [5], in which
the first sealing structure further comprises a conductive via that penetrates the first sealing resin layer, and
the wiring of the redistribution layer and the connection terminal of the second sealing structure are electrically connected through the conductive via.
   [7]

The method according to any one of [1] to [6], in which
the redistribution layer is
formed in a way that includes repeating forming a pattern layer through exposure and development of a photosensitive resin layer and forming a conductor layer, the pattern layer having a pattern including an opening for the wiring and an opening for the trench, the conductor layer comprising a via portion that fills the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [8]

The method according to any one of [1] to [6], in which
the redistribution layer is
formed in a way that includes repeating removing a part of a resin layer with laser irradiation to form a pattern layer and forming a conductor layer, the pattern layer having a pattern including an opening for the wiring and an opening for the trench, the conductor layer comprising a via portion that fills the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [9]

The method according to any one of [1] to [6], in which
the redistribution layer is
formed in a way that includes repeating forming a pattern layer through exposure and development of a photosensitive resin layer and forming a conductor layer, the pattern layer having a pattern including an opening for the wiring, the conductor layer comprising a via portion that fills the opening for the wiring, and
the insulating resin layer is formed by a plurality of the pattern layers, the wiring is formed by a plurality of the conductor layers, and a part of the formed insulating resin layer is removed with laser irradiation to form the trench.
   [10]

The method according to any one of [1] to [9], in which the width of the trench increases in a direction away from the base material.

[11]

The method according to any one of [1] to [10], further comprising mounting the wiring structure on an organic wiring substrate.

[1′]

A method for manufacturing an electronic component device, comprising:
preparing an intermediate structure comprising a base material and a wiring layer, the base material having a first main surface and a second main surface on the rear side of the first main surface, the wiring layer being provided on the first main surface and comprising an insulating resin layer and wiring provided in the insulating resin layer, the base material comprising a resin portion comprising a through portion penetrating from the first main surface to the second main surface, the wiring layer forming a trench having a bottom surface on which the through portion is exposed; and
cutting the through portion along the trench, thereby forming a plurality of wiring structures, each comprising the divided base material and the wiring layer provided on the base material.
   [2′]

The method according to [1′], in which
the resin portion comprises an inorganic filler,
the insulating resin layer does not comprise an inorganic filler, or the insulating resin layer comprises the inorganic filler, and
in a case where the insulating resin layer comprises an inorganic filler, the ratio of the volume of the inorganic filler comprised in the insulating resin layer to the volume of the insulating resin layer is smaller than the ratio of the volume of the inorganic filler comprised in the resin portion to the volume of the resin portion.
   [3′]

The method according to [1′], in which the intermediate structure is prepared in a way that includes forming the wiring layer forming the trench on the base material.

[4]

The method according to [1′], in which the intermediate structure is prepared in a way that includes forming the wiring layer forming the trench on a carrier substrate, and shifting the wiring layer from the carrier substrate onto the base material.

[5]

The method according to any one of [1′] to [4′], in which
the wiring layer is
formed in a way that includes repeating forming a pattern layer through exposure and development of a photosensitive resin layer and forming a conductor layer, the pattern layer having a pattern including an opening for the wiring and an opening for the trench, the conductor layer comprising a via portion filling the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [6′]

The method according to any one of [1′] to [4′], in which
the wiring layer is
formed in a way that includes repeating removing a part of a resin layer with laser irradiation to form a pattern layer and forming a conductor layer, the pattern layer having a pattern including an opening for the wiring and an opening for the trench, the conductor layer comprising a via portion filling the opening for the wiring, and
the insulating resin layer is formed by a plurality of the pattern layers, the wiring is formed by a plurality of the conductor layers, and the trench is formed by connecting a plurality of the openings for the trench formed by a plurality of the pattern layers.
   [7′]

The method according to any one of [1′] to [4′], in which
the wiring layer is
formed in a way that includes repeating forming a pattern layer through exposure and development of a photosensitive resin layer and forming a conductor layer, the pattern layer having a pattern including an opening for the wiring, the conductor layer comprising a via portion filling the opening for the wiring, and
the insulating resin layer is formed by a plurality of the pattern layers, the wiring is formed by a plurality of the conductor layers, and a part of the formed insulating resin layer is removed with laser irradiation to form the trench.
   [8′]

The method according to any one of [1′] to [7′], further comprising mounting a plurality of semiconductor components on the wiring layer, and
in which each of the formed plurality of wiring structures has one or more of the semiconductor components.
   [9′]

The method according to any one of [1′] to [7′], in which
the base material further has an internal wiring layer exposed on the second main surface,
the internal wiring layer forms an internal trench filled with the through portion of the resin portion,
the method further comprises mounting a plurality of semiconductor components on the internal wiring layer,
the through portion is cut along the trench and the internal trench, and
each of the formed plurality of wiring structures comprises one or more of the semiconductor components.
   [10′]

The method according to [8′] or [9′], in which
the base material further comprises a relay wiring portion comprising relay wiring electrically connected to a plurality of the semiconductor components, and the relay wiring portion is sealed by the resin portion, and
the formed plurality of wiring structures each comprises the relay wiring portion and two or more of the semiconductor components electrically connected via the relay wiring portion.
   [11′]

The method according to any one of [1′] to [10′], in which the width of the trench increases in the direction away from the base material.

[12′]

The method according to any one of [1′] to [11′], further comprising mounting the wiring structure on an organic wiring substrate.

### Advantageous Effects of Invention

A method is disclosed for easily manufacturing a wiring structure including a base material that has a resin portion containing a lot of inorganic fillers and a wiring layer provided on the base material. This method is applicable, for example, to the fabrication of 2.3-dimensional semiconductor packages.

### BRIEF DESCRIPTION OF DRAWINGS

FIG. 1 is a process diagram illustrating an example of a method for manufacturing an electronic component device.

FIG. 2 is a process diagram illustrating an example of a method for manufacturing an electronic component device.

FIG. 3 is a process diagram illustrating an example of a method for manufacturing an electronic component device.

FIG. 4 is a process diagram illustrating an example of a method for manufacturing an electronic component device.

FIG. 5 is a process diagram illustrating an example of a method for manufacturing an electronic component device having a semiconductor component.

FIG. 6 is a process diagram illustrating an example of a method for manufacturing an electronic component device having a semiconductor component.

FIG. 7 is a process diagram illustrating an example of a method for manufacturing an electronic component device having a semiconductor component.

FIG. 8 is a process diagram illustrating an example of a method for manufacturing an electronic component device having a semiconductor component.

FIG. 9 is a process diagram illustrating an example of a method for manufacturing an electronic component device having a semiconductor component.

FIG. 10 is a process diagram illustrating an example of a method for manufacturing an electronic component device having a semiconductor component.

FIG. 11 is a process diagram illustrating an example of a method for manufacturing an electronic component device having a semiconductor component.

FIG. 12 is a process diagram illustrating an example of a method for manufacturing an electronic component device having a semiconductor component.

FIG. 13 is a process diagram illustrating an example of a method for manufacturing an electronic component device having a semiconductor component.

FIG. 14 is a process diagram illustrating an example of a method for manufacturing an electronic component device having a semiconductor component.

FIG. 15 is a process diagram illustrating an example of a method for manufacturing an electronic component device having a semiconductor component.

FIG. 16 is a process diagram illustrating an example of a method for manufacturing an electronic component device having a semiconductor component.

FIG. 17 is a process diagram illustrating an example of a method for manufacturing an electronic component device having a semiconductor component.

### DESCRIPTION OF EMBODIMENTS

The present disclosure is not limited to the following examples. In the following examples, duplicated descriptions may be omitted.

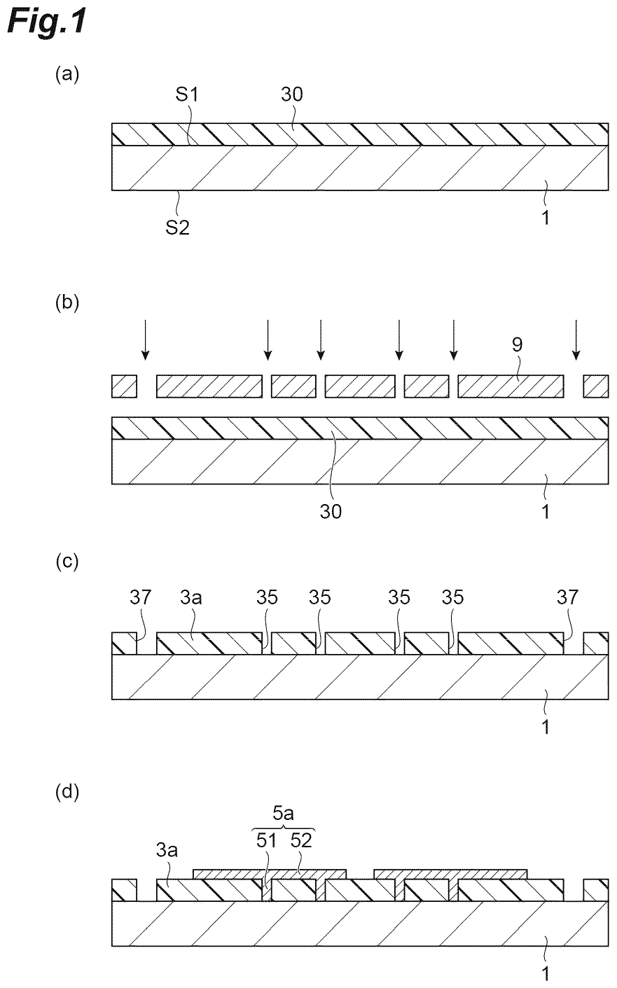

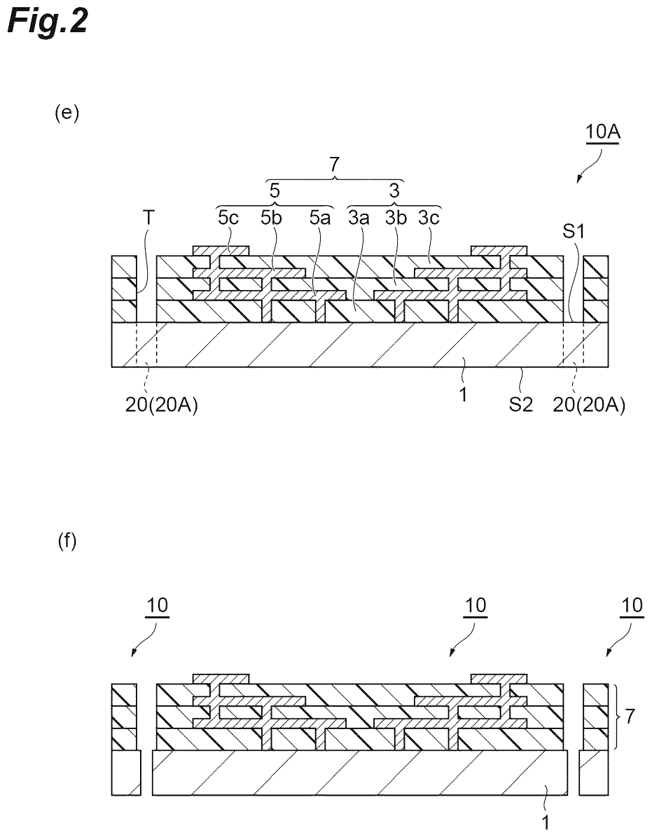

FIGS. 1 and 2 are process diagrams illustrating an example of a method for manufacturing an electronic component device. The method illustrated in FIG. 1 and FIG. 2 includes preparing an intermediate structure 10A having a base material 1 and a wiring layer 7. The base material 1 has a first main surface S1 and a second main surface S2 on the rear side of the first main surface S1. The wiring layer 7 is provided on the first main surface S1 and has an insulating resin layer 3 and wiring 5 provided in the insulating resin layer 3. The base material 1 has a resin portion 20 including a through portion 20A penetrating from the first main surface S1 to the second main surface S2. The insulating resin layer 3 forms a trench T having a bottom surface that exposes the through portion 20A. The method also includes cutting the through portion 20A along the trench T to form a plurality of wiring structures 10, each having the base material 1 divided and the wiring layer 7 provided on the base material 1.

The through portion 20A is a portion of the resin portion 20 that penetrates from the first main surface S1 to the second main surface S2. The resin portion 20 includes at least the through portion 20A and can be a member integrally formed from a resin material such as a sealing material. The entire first main surface S1 of the base material 1 may also be the surface of the resin portion 20. Alternatively, in addition to the resin portion 20 including the through portion 20A, a relay wiring portion, a semiconductor component, or both of these described below may be provided in the base material 1, with the relay wiring portion or the semiconductor component exposed to the first main surface S1.

The resin portion 20 may contain a resin and an inorganic filler. The insulating resin layer 3 may contain a resin and an inorganic filler. In the case where the insulating resin layer 3 contains an inorganic filler, the ratio of the volume of the inorganic filler contained in the insulating resin layer 3 to the volume of the insulating resin layer 3 is smaller than the ratio of the volume of the inorganic filler contained in the resin portion 20 to the volume of the resin portion 20. Due to the difference in the ratio of inorganic fillers, the resin portion 20 is relatively harder. Different hardnesses often result in different suitable cutting conditions, but according to the method disclosed herein, since only the resin portion 20 (the through portion 20A) is cut, it is possible to employ cutting conditions suitable for cutting the resin portion 20 while avoiding any influence on the insulating resin layer 3. The resin portion 20 (the through portion 20A) is cut, for example, by a rotating blade.

The ratio of the volume of the inorganic filler in the resin portion 20 to the volume of the resin portion 20 may be, for example, 10% or more and 95% or less by volume. The ratio of the volume of the inorganic filler in the insulating resin layer 3 to the volume of the insulating resin layer 3 may be, for example, 0% or more and 50% or less by volume.

In the example of FIGS. 1 and 2, the wiring layer 7 is formed by repeatedly forming a pattern layer 3a having a pattern including an opening for the wiring 35 used for the wiring and an opening for the trench 37 used for the trench by exposing and developing a photosensitive resin layer 30 formed on the first main surface S1 of the base material 1, and forming a conductor layer 5a including a via portion 51 filling the opening for the wiring 35 and a wiring pattern portion 52 provided on the pattern layer 3a. The insulating resin layer 3 is formed by the first pattern layer 3a, a second pattern layer 3b, and a third pattern layer 3c, which are formed in sequence from the side of the base material 1. The wiring 5 is formed by the first conductor layer 5a, a second conductor layer 5b, and a third conductor layer 5c, which are formed in sequence from the side of the base material 1. The trench T penetrating the insulating resin layer 3 is formed by connecting the multiple openings for the trench 37 formed by the plurality of pattern layers 3a, 3b, and 3c.

The photosensitive resin layer 30 and the pattern layers 3a, 3b, and 3c can be formed using conventional resist materials that are used to form an insulating resin layer of a wiring layer. For the exposure of the resin layer 30, active light rays such as ultraviolet light are applied through a mask 9, which has an opening provided at a position corresponding to the opening for the wiring 35 and the opening for the trench 37. Instead of using the exposure and development method, a part of the resin layer 30 may be removed by laser irradiation to form the pattern layers 3a, 3b, and 3c, which have a pattern including the opening for the wiring 35 and the opening for the trench 37. In this case, the resin layer 30 may be non-photosensitive.

The conductor layers 5a, 5b, and 5c and the wiring 5 can be formed using conventional methods such as plating, printing of conductor paste, or sputtering.

The wiring layer 7 is used, for example, as a redistribution layer connected to a semiconductor component including an IC chip. The number of pattern layers and conductor layers that constitute the wiring layer 7 is not limited to a particular number, but may be, for example, 2 or more and 8 or less, respectively. The thickness of the entire wiring layer 7 may be, for example, 10 μm or more and 150 μm or less.

The intermediate structure 10A may be prepared by a method that includes forming the wiring layer 7, which forms the trench T, on a carrier substrate separate from the base material 1, and shifting the wiring layer 7 from the carrier substrate onto the base material 1.

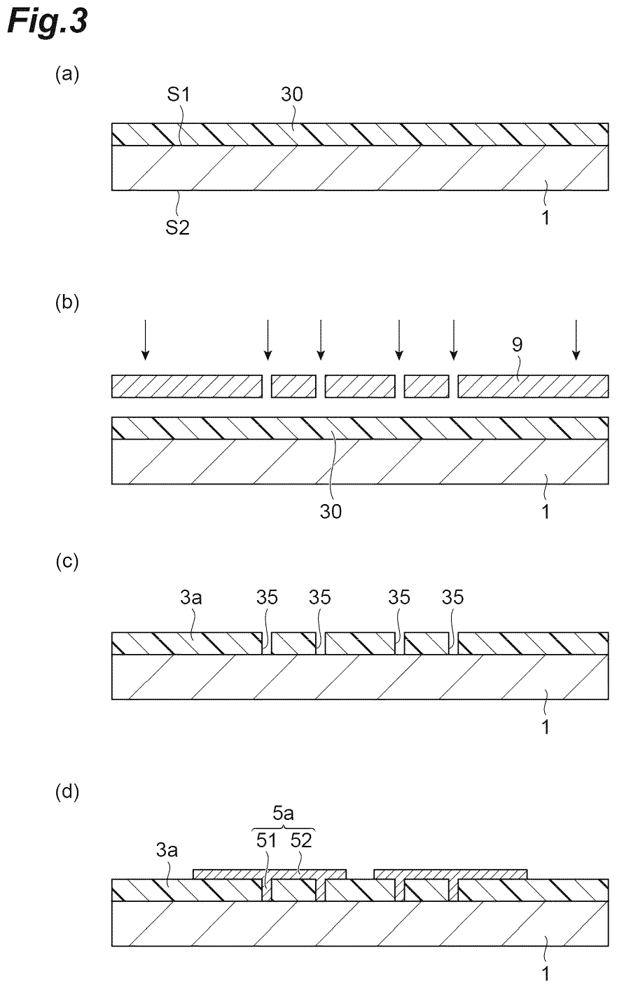

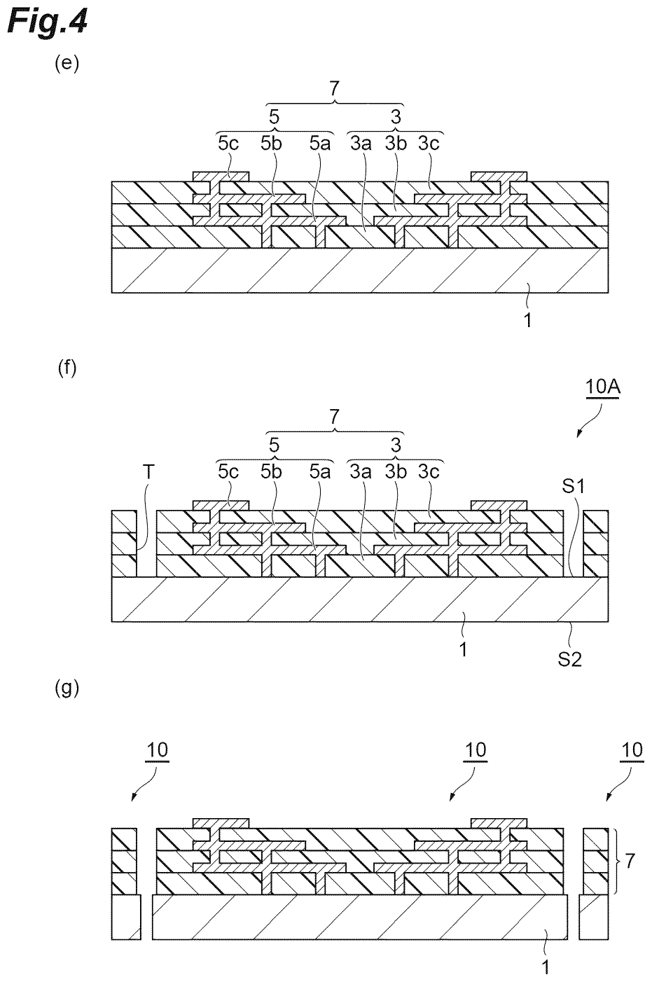

FIGS. 3 and 4 are process diagrams illustrating another exemplary method for manufacturing an electronic component device. In the case of the method illustrated in FIGS. 3 and 4, the wiring layer 7 is formed in a way, which includes repeatedly forming a pattern layer 3a having a pattern including an opening for the wiring 35 used for the wiring by exposure and development of the photosensitive resin layer 30 and forming a conductor layer 5a including a via portion 51 that fills the opening for the wiring 35 and a wiring pattern portion 52 provided on the pattern layer 3a. As in the method for FIGS. 1 and 2, the insulating resin layer 3 is formed by the plurality of pattern layers 3a, 3b, and 3c, and the wiring 5 is formed by the plurality of conductor layers 5a, 5b, and 5c. Then, as illustrated in FIG. 4(f), a part of the formed insulating resin layer 3 is removed using laser irradiation to form the trench T.

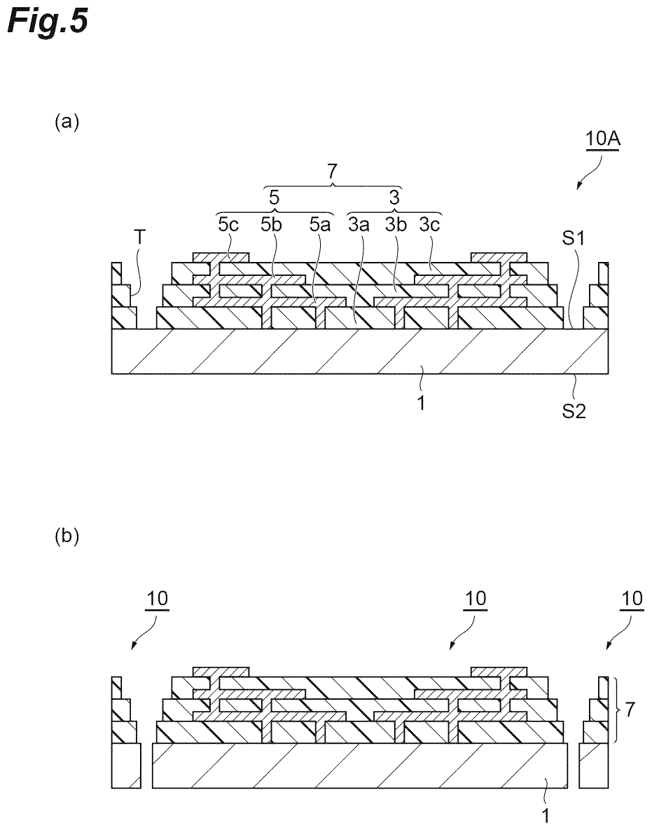

As illustrated in another example in FIG. 5, the trench T may be formed with a width that widens in the direction away from the base material 1. By varying the width of the opening for the trench formed by the multiple pattern layers 3a, 3b, and 3c, it is possible to form the trench T with a gradually widening width. In the case where the end face of the trench T (insulating resin layer 3) is inclined in this way, the occurrence of cracks or delamination starting from the edge of the insulating resin layer 3 can be suppressed.

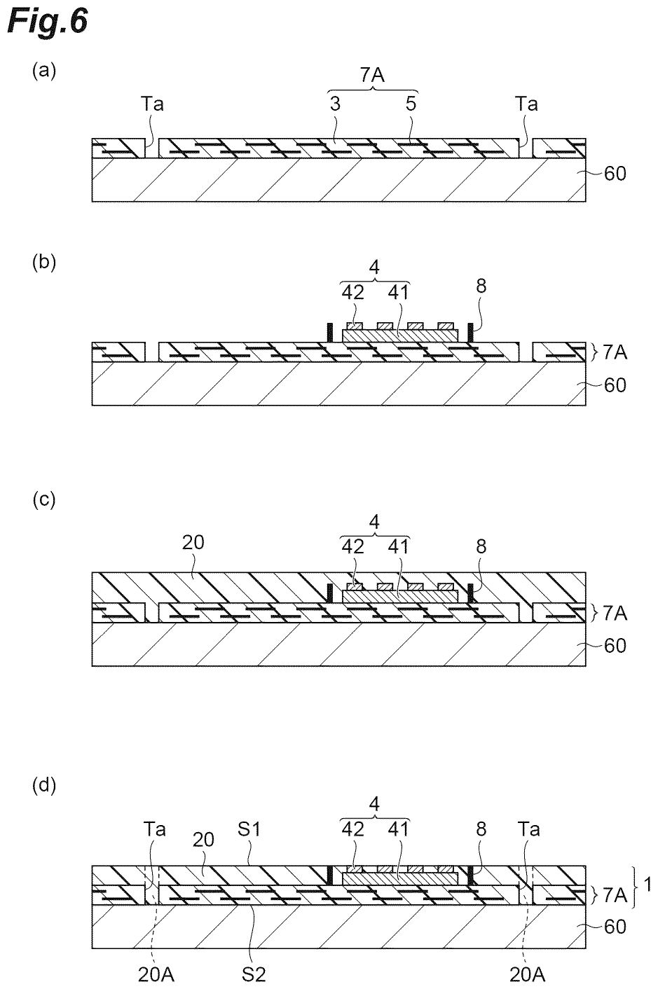

FIGS. 6, 7, 8, and 9 are process diagrams illustrating an example of a method for manufacturing an electronic component device having multiple semiconductor components. In the method illustrated in FIGS. 6 to 9, as illustrated in FIG. 6, the base material 1 is formed in a way that includes forming an internal wiring layer 7A forming an internal trench Ta, arranging a relay wiring portion 4 and a copper pillar 8 on the internal wiring layer 7A, forming the resin portion 20 that seals the relay wiring portion 4, and removing the surface layer portion of the resin portion 20 opposite to the internal wiring layer 7A to form a flat surface that exposes the relay wiring portion 4 and the copper pillar 8. The base material 1 being formed includes the internal wiring layer 7A, the relay wiring portion 4, and the resin portion 20. The resin portion 20 includes a portion that fills the internal trench Ta of the internal wiring layer 7A and includes a through portion 20A that penetrates from the first main surface S1 to the second main surface S2 on the rear side. The internal wiring layer 7A is exposed on the second main surface S2 of the base material 1. The internal wiring layer 7A can be formed by exposure and development of a photosensitive resin layer, laser irradiation, or a combination of these, similar to the method illustrated in FIGS. 1 to 4.

The relay wiring portion 4 has a main body 41 including relay wiring electrically connected to a plurality of semiconductor components and has a terminal 42 provided on the outer surface of the main body 41. The relay wiring portion 4 is arranged on the internal wiring layer 7A in the orientation in which the terminal 42 is positioned on the side opposite to the internal wiring layer 7A. The relay wiring portion 4 may be a silicon interposer including a silicon substrate. The copper pillar 8 can be formed using conventional by conventional methods such as plating or printing of a conductive paste. The copper pillar 8 is electrically connected to the wiring 5 in the internal wiring layer 7A.

The resin portion 20 can be formed using conventional sealing materials such as a thermosetting resin composition containing an inorganic filler. The inorganic filler may include, for example, silica particles.

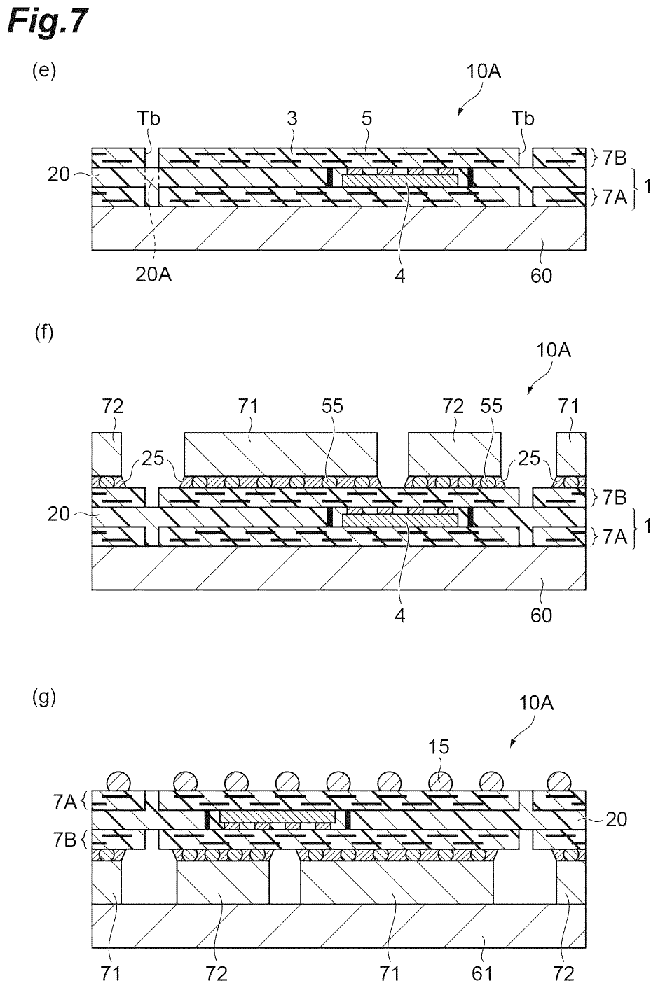

Subsequently, as illustrated in FIG. 7(e), a wiring layer 7B is formed on the first main surface S1 of the base material 1, forming a trench Tb having a bottom surface that exposes the through portion 20A. The trench Tb is formed at a position overlapping with the internal trench Ta when viewed from the thickness direction of the base material 1. The wiring layer 7B can be formed using a method similar to that illustrated in FIGS. 1 to 4. The wiring 5 in the wiring layer 7B is electrically connected to the relay wiring portion 4 and the copper pillar 8.

On the formed wiring layer 7B, a plurality of semiconductor components 71 and 72 are mounted (FIG. 7(f)). The semiconductor components 71 and 72 each have a bump 55, and the semiconductor components 71 and 72 are electrically connected to the wiring layer 7B via the bump 55. The space between the semiconductor components 71 and 72 and the wiring layer 7B is filled with an underfill material 25.

The intermediate structure 10A having the base material 1, the wiring layer 7B, and the semiconductor components 71 and 72 is shifted onto a carrier substrate 61, which is separate from the carrier substrate 60, in the orientation in which the semiconductor components 71 and 72 are positioned on the side of the carrier substrate 61, and in this state, a bump 15 is provided on the internal wiring layer 7A (FIG. 7(g)).

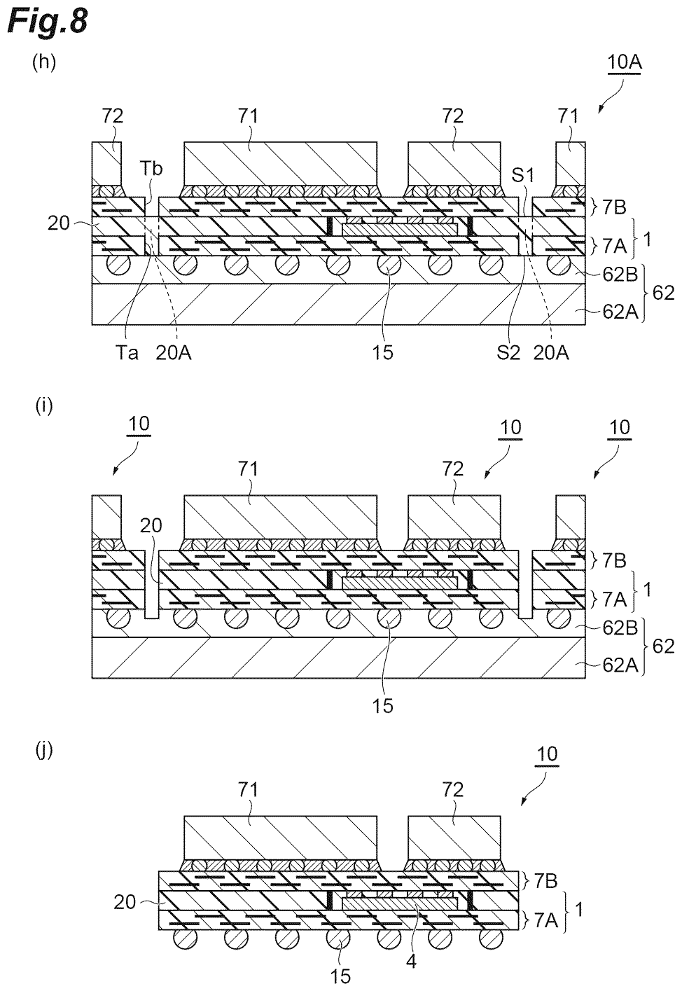

Then, as illustrated in FIG. 8(a), the intermediate structure 10A is shifted onto another carrier substrate 62. The carrier substrate 62 has a support substrate 62A and a temporary fixing material layer 62B provided on the support substrate 62A. The intermediate structure 10A is temporarily fixed to the carrier substrate 62 in the orientation in which the bump 15 contacts the temporary fixing material layer 62B. In this state, the through portion 20A of the resin portion 20 is cut from the side of the trench Tb along the trench Tb and the internal trench Ta, and thus a plurality of wiring structures 10 is formed on the carrier substrate 62 (FIG. 8(i)).

The wiring structure 10 is delaminated from the carrier substrate 62 (FIG. 8(j)). The wiring structure 10 is an electronic component device having the relay wiring portion 4 and the plurality of semiconductor components 71 and 72, that is, a semiconductor package. The plurality of semiconductor components 71 and 72 are electrically connected through the relay wiring portion 4. The semiconductor components 71 and 72 constituting one wiring structure 10 can be components having different functions. For example, the semiconductor component 71 may be a system-on-chip (SoC), and the semiconductor component 72 may be a memory. A single wiring structure 10 (semiconductor package) may also have a plurality of semiconductor components of the same type.

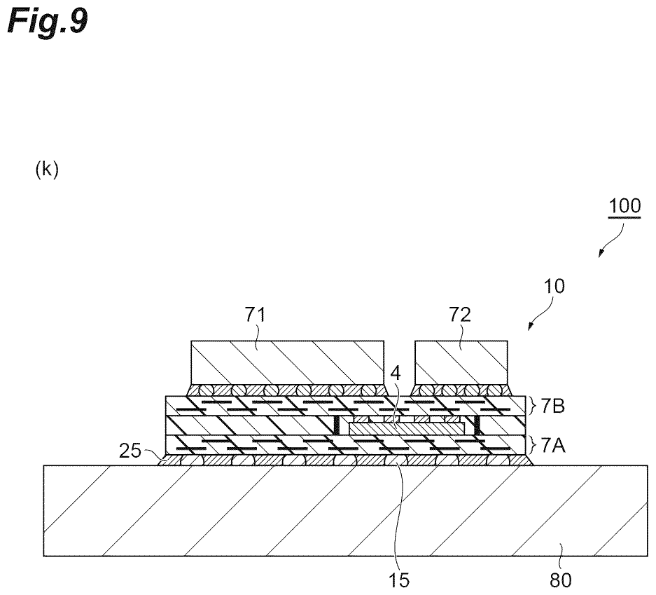

As illustrated in FIG. 9, the wiring structure 10 is mounted on an organic wiring substrate 80 to obtain an electronic component device 100. The wiring structure 10 is electrically connected to the organic wiring substrate 80 via the bump 15. The underfill material 25 may be filled between the wiring structure 10 and the organic wiring substrate 80. Various electronic components other than the wiring structure 10 may be mounted on one organic wiring substrate 80.

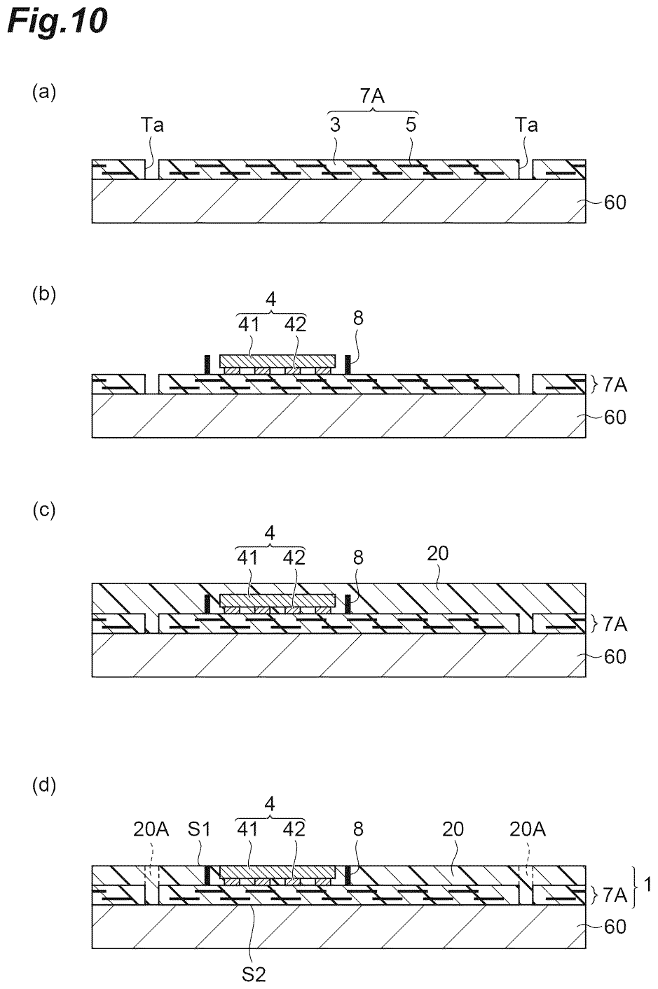

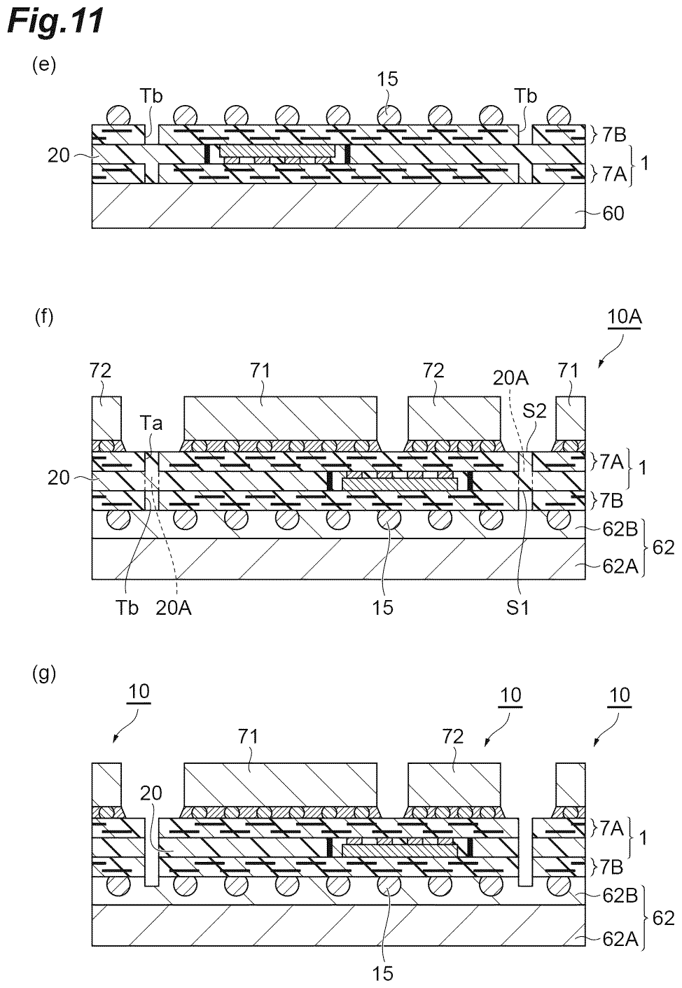

FIGS. 10 and 11 are process diagrams illustrating another example of a method for manufacturing an electronic component device having multiple semiconductor components. The method illustrated in FIGS. 10 and 11 differs from the methods illustrated in FIGS. 7 to 9 in that the relay wiring portion 4 is arranged on the internal wiring layer 7A in the orientation in which the terminal 42 is positioned on the side of the internal wiring layer 7A (FIG. 10(b)), and in that multiple semiconductor components 71 and 72 are mounted on the internal wiring layer 7A (FIG. 11(f)). The bump 15 is provided on the wiring layer 7B with the intermediate structure 10A temporarily fixed to the carrier substrate 60 (FIG. 11(e)).

As illustrated in FIGS. 11(f) and 11(g), while the intermediate structure 10A is temporarily fixed to the carrier substrate 62, the through portion 20A of the resin portion 20 is cut from the side of the internal trench Ta along the trench Tb and the internal trench Ta to form the plurality of wiring structures 10 on the carrier substrate 62. The formed wiring structures 10 can be delaminated from the carrier substrate 62 and mounted on an organic wiring substrate.

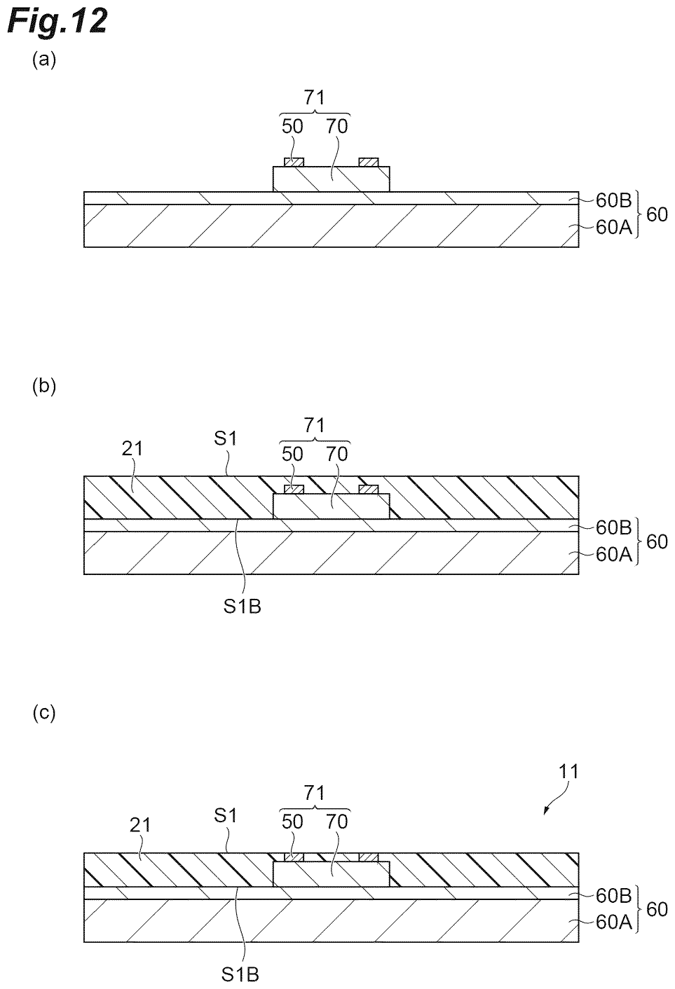

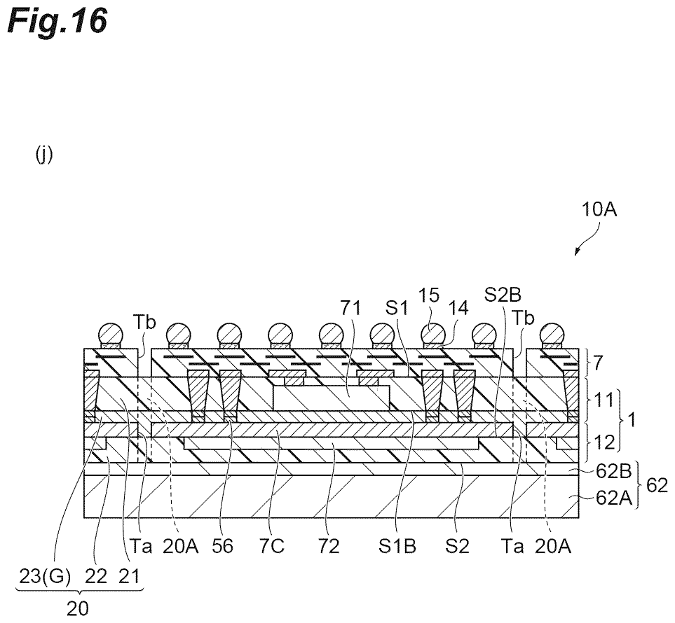

FIGS. 12, 13, 14, 15, 16, and 17 are also process diagrams illustrating, in partial cross-section, an example of a method for manufacturing an electronic component device (semiconductor package) having multiple semiconductor components. In this example, as illustrated in FIG. 16, the base material 1 includes a first sealing structure 11, a second sealing structure 12, and an underfill layer 23 formed between them. The first sealing structure 11 has a first sealing resin layer 21 having a first main surface S1 and a rear surface S1B on the rear side of the first main surface S1, and a plurality of first semiconductor components 71 sealed by the first sealing resin layer 21 and connected to the wiring of the redistribution layer 7. The second sealing structure 12 has a second sealing resin layer 22 having a second main surface S2 and a rear surface S2B on the rear side thereof, a buildup layer 7C provided to contact the rear surface S2B, a plurality of second semiconductor components 72 sealed by the second sealing resin layer 22 on the buildup layer 7C, and a plurality of connection terminals 56 provided on the side of the buildup layer 7C opposite to the second sealing resin layer 22. The redistribution layer 7 forms a trench Tb having a bottom surface that exposes the first sealing resin layer 21. When viewed from the thickness direction of the base material 1, the width between adjacent trenches Tb is larger than the width of the first semiconductor components 71. The buildup layer 7C forms an internal trench Ta having a bottom surface that exposes the second sealing resin layer 22. When viewed from the thickness direction of the base material 1, the width between adjacent internal trenches Ta is larger than the width of the second semiconductor components 72.

The second sealing structure 12 is arranged so that a gap G is formed between the first sealing structure 11 and the second sealing structure 12 in the orientation in which the connection terminal 56 is in contact with the first sealing structure 11. The first sealing structure 11 and the second sealing structure 12 are arranged so that the bottom surface of the trench Tb and the bottom surface of the internal trench Ta overlap when viewed from the thickness direction of the base material 1. The underfill layer 23 fills the periphery of the connection terminal 56 in the gap G and fills the internal trench Ta. However, the underfill layer 23 does not necessarily completely fill the gap G and the internal trench Ta.

In the case of the example of FIGS. 12 to 17, the intermediate structure 10A having the base material 1 and the redistribution layer 7 is prepared, and then the through portion 20A is cut along the trench Tb and the internal trench Ta to form the plurality of wiring structures 10 having the base material 1 and the redistribution layer 7. Each of the formed plurality of wiring structures 10 has one or more first semiconductor components 71 and one or more second semiconductor components 72. For example, the first semiconductor component 71 may be a system-on-chip (SoC), and the second semiconductor component 72 may be a memory.

To provide the first sealing structure 11 constituting the intermediate structure 10A, as illustrated in FIG. 12(a), the carrier substrate 60 having a support substrate 60A and a temporary fixing material layer 60B provided on the support substrate 60A is prepared, and a semiconductor chip 70 and a first semiconductor component 71 having a connection terminal 50 provided on one main surface side of the semiconductor chip 70 are temporarily fixed on the temporary fixing material layer 60B of the carrier substrate 60. The plurality of first semiconductor components 71 are arranged on one carrier substrate 60. Then, the first sealing resin layer 21 that seals the plurality of first semiconductor components 71 is formed on the carrier substrate 60 (FIG. 12(b)). The first sealing resin layer 21 is a plate-shaped resin molded body having the first main surface S1, which is opposite to the carrier substrate 60, and the rear surface S2B on the rear side of the first main surface S1. The rear surface S2B of the first sealing resin layer 21 contacts the carrier substrate 60. The first semiconductor component 71 is sealed inside the first main surface S1. A part of the first sealing resin layer 21 is removed from the side of the first main surface S1 to form the first sealing structure 11 that is composed of both the first semiconductor component 71 and the first sealing resin layer 21 and has the first main surface S1 that exposes the first semiconductor component 71 (FIG. 12(c)). The first sealing resin layer 21 can be a layer containing resin and inorganic filler formed from resin materials such as conventional sealing materials, as in the example of the resin portion 20 described above. The first sealing resin layer 21 can be removed using conventional methods such as chemical-mechanical polishing.

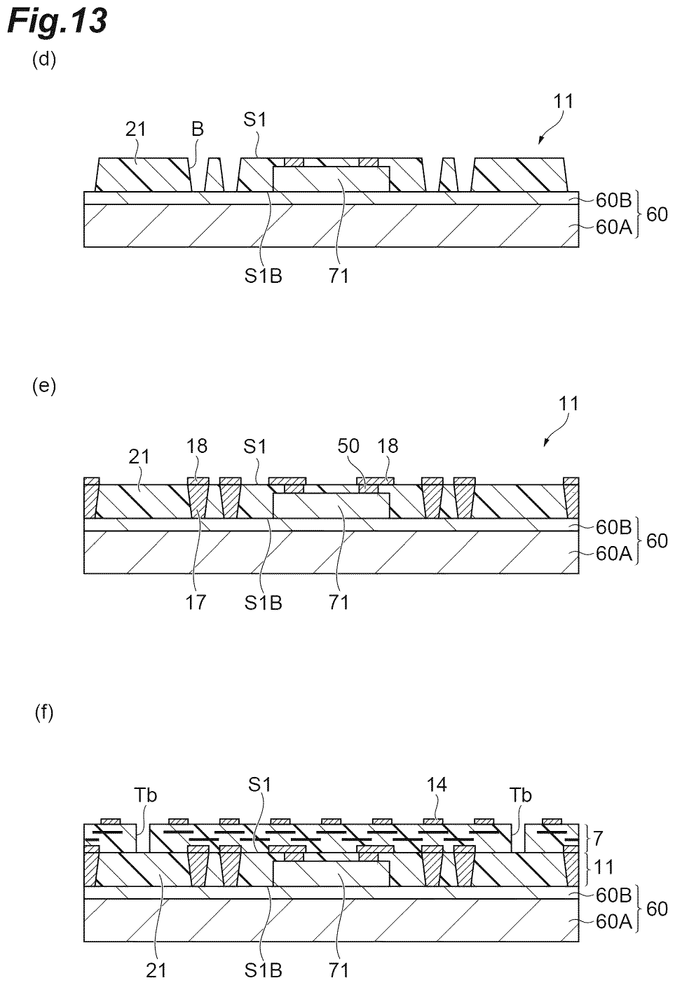

As illustrated in FIG. 13(d), a plurality of via holes B are formed penetrating the first sealing resin layer 21 from the first main surface S1 to the rear surface 1B. Then, as illustrated in FIG. 13(e), a conductive via 17 is formed to fill the via hole B, and wiring 18 is formed on the first main surface S1. The wiring 18 includes a part connected to the connection terminal 50 of the first semiconductor component 71 or the conductive via 17.

Subsequently, as illustrated in FIG. 13(f), the redistribution layer 7 is formed on the first sealing structure 11, forming the trench Tb having a bottom surface that exposes the first sealing resin layer 21. The redistribution layer 7 has an insulating resin layer and wiring provided in the insulating resin layer, and it may have a plurality of electrodes 14 provided on the side opposite to the first sealing structure 11. The redistribution layer 7 can be formed in a method similar to that of the wiring layer described above. The trench Tb is formed between adjacent first semiconductor components in the first sealing structure 11. The first sealing resin layer 21 includes the through portion penetrating from the bottom surface (first main surface S1) of the trench Tb to the rear surface S1B.

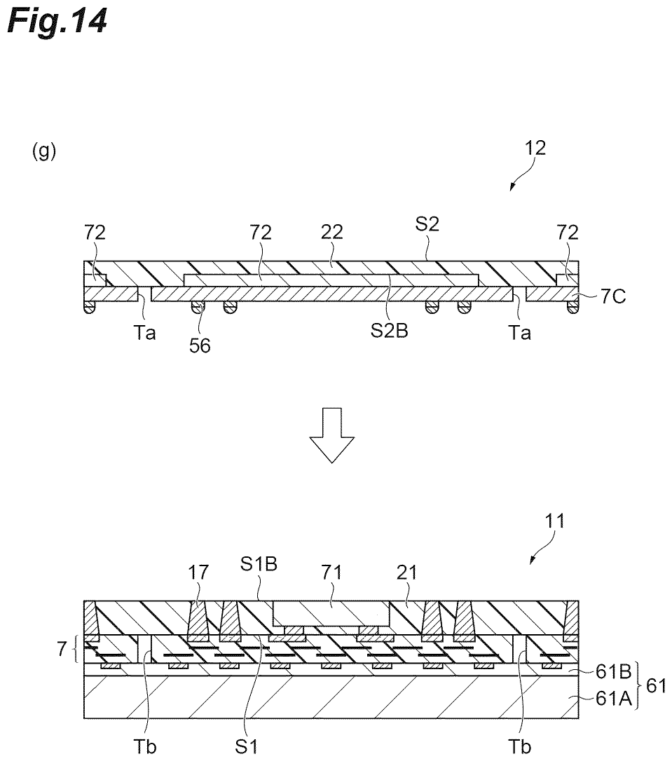

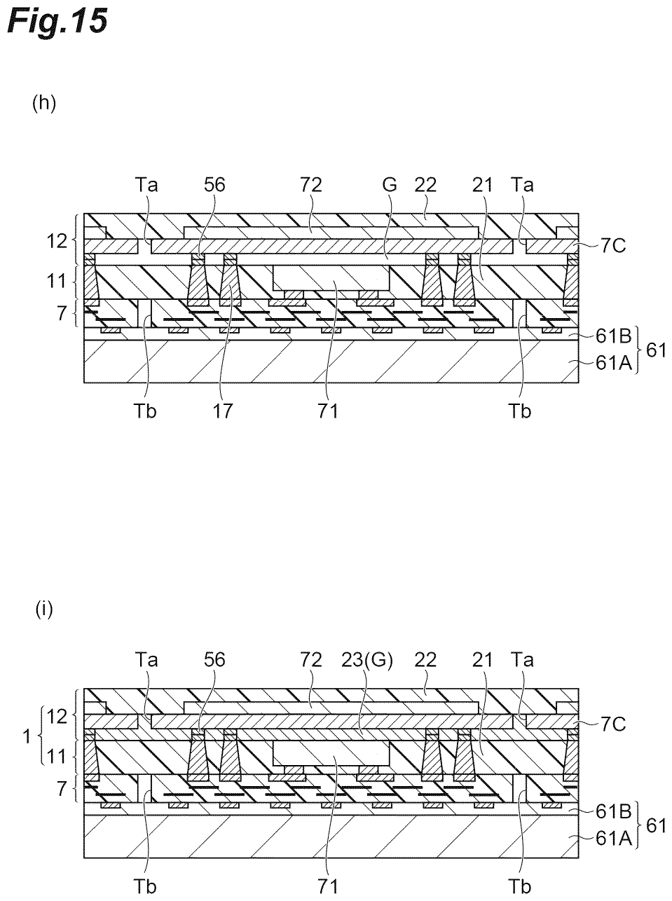

As illustrated in FIG. 14(g) and FIG. 15(h), the first sealing structure 11 is temporarily fixed on another carrier substrate 61 in the orientation in which the redistribution layer 7 faces the carrier substrate 61. In this state, the second sealing structure 12, which is separately prepared, is placed on the first sealing structure 11 in the orientation in which the connection terminal 56 faces the first sealing structure 11, so that the gap G is formed between the first sealing structure 11 and the second sealing structure 12. The carrier substrate 61 has a support substrate 61A and a temporary fixing material layer 61B, similar to the carrier substrate 60.

The second sealing structure 12 is composed of the buildup layer 7C, the plurality of second semiconductor components 72 provided on the buildup layer 7C, and the second sealing resin layer 22 that seals the second semiconductor components 72 on the buildup layer 7C. The second sealing resin layer 22 can be a layer containing resin and inorganic filler, similar to the first sealing resin layer 21. The buildup layer 7C can have the insulating resin layer and the wiring provided in the insulating resin layer, similar to the redistribution layer 7. The wiring of the buildup layer 7C is connected to the second semiconductor components 72. The buildup layer 7C forms an internal trench Ta having a bottom surface that exposes the second sealing resin layer 22. The second sealing resin layer 22 includes the through portion that penetrates from the bottom surface of the internal trench Ta to the second main surface S2. The buildup layer 7C that forms the internal trench Ta can be formed by a method similar to that of the wiring layer that forms the trench T (or the redistribution layer 7 that forms the trench Tb). The connection terminal 56 of the second sealing structure 12 is electrically connected to the wiring in the buildup layer 7C, and it may be formed by an electrode and a bump. At least a part of the multiple connection terminals 56 is connected to the conductive via 17 of the first sealing structure 11.

As illustrated in FIG. 15(i), the underfill layer 23 is formed to fill the periphery of the connection terminal 56 in the gap G between the first sealing structure 11 and the second sealing structure 12. The underfill layer 23 fills a part or the whole of the internal trench Ta. The underfill layer 23 can be a layer containing a resin and an inorganic filler, similar to the resin portion 20. In this stage, the base material 1 composed of the first sealing structure 11, the second sealing structure 12, and the underfill layer 23 is formed.

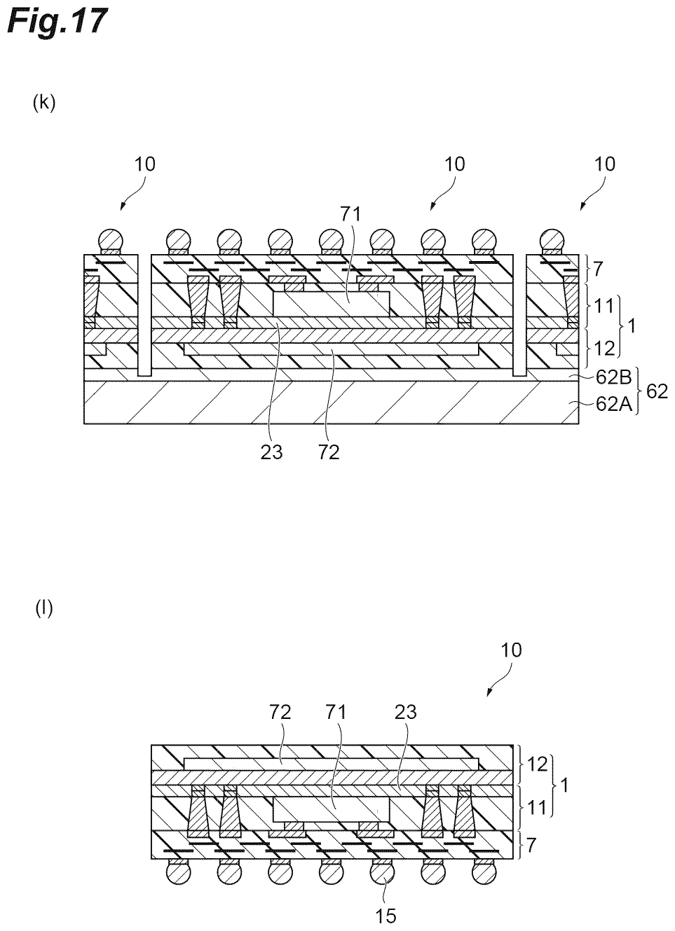

As illustrated in FIG. 16, the base material 1 and the redistribution layer 7 are temporarily fixed on a carrier substrate 62 other than the carrier substrate 61 in the orientation in which the redistribution layer 7 faces the side opposite to the carrier substrate 62. The carrier substrate 62 has a support substrate 62A and a temporary fixing material layer 62B provided on the support substrate 62A. In the base material 1, the resin portion 20 is constituted by the first sealing resin layer 21, the underfill layer 23, and the second sealing resin layer 22. When viewed from the thickness direction of the base material 1, the first sealing resin layer 21, the underfill layer 23, and the second sealing resin layer 22 are the through portions 20A where the bottom surface of the trench Tb and the bottom surface of the internal trench Ta overlap. In this state, as illustrated in FIG. 17(k), the base material 1 (resin portion 20) is cut at the position of the through portion 20A along the trench Tb and the internal trench Ta to form the plurality of wiring structures 10 on the carrier substrate 62. Before or after the base material 1 is cut, the bump 15 may be formed on the electrode 14 of the redistribution layer 7. The formed wiring structures 10 are separated from the carrier substrate 62 as illustrated in FIG. 17 (1). The obtained wiring structure 10 may be used as a semiconductor package. Alternatively, the wiring structure 10 may be mounted on an organic wiring substrate (semiconductor package substrate), obtaining a semiconductor package having the wiring structure 10 and the semiconductor package substrate.

The resin portion 20 (first sealing resin layer 21, second sealing resin layer 22, and underfill layer 23) may contain a resin and an inorganic filler. The insulating resin layer in the redistribution layer 7 may contain an inorganic filler. The insulating resin layer in the buildup layer 7C may contain an inorganic filler. In the insulating resin layer of the redistribution layer 7, the insulating resin layer of the buildup layer, or both, the ratio of the volume of the inorganic filler to the volume of the insulating resin layer may be smaller than the ratio of the volume of the inorganic filler contained in the resin portion to the volume of the resin portion. In the case where the proportion of inorganic filler differs in the first sealing resin layer 21, the second sealing resin layer 22, and the underfill layer 23, the proportion of the volume of inorganic filler in the insulating resin layer of the redistribution layer 7 or the buildup layer 7C may be smaller than the smallest proportion of the volume of inorganic filler in each layer.

The proportion of the volume of inorganic filler in the first sealing resin layer 21, the second sealing resin layer 22, and the underfill layer 23 to the volume of each layer may be, for example, 10% or more and 95% or less by volume. The proportion of the volume of inorganic filler in the insulating resin layer of the redistribution layer 7 and the buildup layer 7C to the volume of the insulating resin layer may be, for example, 0% or more and 50% or less by volume.

### REFERENCE SIGNS LIST

1 base material
3 insulating resin layer
5 wiring
3a, 3b, 3c pattern layer
4 relay wiring portion
5a, 5b, 5c conductor layer
7,7B wiring layer (redistribution layer)
7A internal wiring layer
7C buildup layer
10 wiring structure (semiconductor package)
11 first sealing structure
12 second sealing structure
10A intermediate structure
17 conductive via
20 resin portion
20A through portion
21 first sealing resin layer
22 second sealing resin layer
23 underfill layer
30 resin layer
35 opening for wiring
37 opening for trench
51 via portion
52 wiring pattern portion
60, 61, 62 carrier substrate
71 semiconductor component (first semiconductor component)
72 semiconductor component (second semiconductor component)
80 organic wiring substrate
100 electronic component device
S1 first main surface of base material
S1B rear side of the first sealing resin layer
S2 second main surface of base material
S2B rear side of the second sealing resin layer
T, Tb trench
Ta internal trench

1. A method for manufacturing a semiconductor package, comprising:
preparing an intermediate structure comprising a base material and a redistribution layer, the base material having a first main surface and a second main surface on a rear side of the first main surface, the redistribution layer being provided on the first main surface and comprising an insulating resin layer and wiring provided in the insulating resin layer, the base material comprising a resin portion comprising a through portion penetrating from the first main surface to the second main surface, the redistribution layer forming a trench having a bottom surface on which the through portion is exposed; and
cutting the through portion along the trench, thereby forming a plurality of wiring structures, each comprising the divided base material and the redistribution layer provided on the base material,
wherein the base material comprises:
a first sealing structure comprising a first sealing resin layer with the first main surface and a rear surface on a rear side of the first main surface, and a plurality of first semiconductor components sealed by the first sealing resin layer and connected to the wiring of the redistribution layer;
a second sealing structure comprising a second sealing resin layer having the second main surface and a rear surface on a rear side of the second main surface, a buildup layer being in contact with the rear surface, a plurality of second semiconductor components sealed by the second sealing resin layer on the buildup layer, and a plurality of connection terminals provided on a side of the buildup layer opposite to the second sealing resin layer; and
an underfill layer,
the buildup layer forms an internal trench having a bottom surface on which the second sealing resin layer is exposed,
the second sealing structure is arranged so that a gap is formed between the first sealing structure and the second sealing structure in an orientation in which the connection terminal is in contact with the first sealing structure, and the first sealing structure and the second sealing structure are arranged so that the bottom surface of the trench and the bottom surface of the internal trench overlap when viewed from a thickness direction of the base material,
the underfill layer fills a periphery of the connection terminal in the gap and the internal trench,
the resin portion comprises the first sealing resin layer, the underfill layer, and the second sealing resin layer,
the through portion is cut along the trench and the internal trench, and
each of the plurality of wiring structures being formed has one or more of the first semiconductor components and one or more of the second semiconductor components.

2. The method according to claim 1, wherein the resin portion comprises an inorganic filler.

3. The method according to claim 2, wherein
the insulating resin layer does not comprise an inorganic filler, or the insulating resin layer comprises the inorganic filler, and
in a case where the insulating resin layer comprises the inorganic filler, a ratio of a volume of the inorganic filler comprised in the insulating resin layer to a volume of the insulating resin layer is smaller than a ratio of a volume of the inorganic filler comprised in the resin portion to a volume of the resin portion.

4. The method according to claim 1, wherein the intermediate structure is prepared in a way that includes forming the redistribution layer having the trench being formed in the redistribution layer on the base material.

5. The method according to claim 1, wherein
the intermediate structure is prepared in a way that includes
forming the redistribution layer forming the trench on the first sealing structure;
arranging the second sealing structure on a side of the first sealing structure opposite to the redistribution layer in an orientation in which the connection terminal is in contact with the second sealing structure so that a gap is formed between the first sealing structure and the second sealing structure and so that the bottom surface of the trench overlaps with the bottom surface of the internal trench when viewed in the thickness direction of the base material; and
forming an underfill layer that fills a periphery of the connection terminal in the gap and fills the internal trench.

6. The method according to claim 1, wherein
the first sealing structure further comprises a conductive via that penetrates the first sealing resin layer, and
the wiring of the redistribution layer and the connection terminal of the second sealing structure are electrically connected through the conductive via.

7. The method according to claim 1, further comprising:
repeating a process of forming a pattern layer through exposure and development of a photosensitive resin layer to form a plurality of pattern layers, each of the pattern layers having a pattern including an opening for the wiring and an opening for the trench, the plurality of the pattern layers forming a plurality of openings for the trench; and
repeating a process of forming a conductor layer comprising a via portion that fills the opening for the wiring to form a plurality of conductor layers, wherein
the insulating resin layer of the redistribution layer is formed by the plurality of the pattern layers,
the wiring of the redistribution layer is formed by the plurality of the conductor layers, and
the trench is formed by connecting the plurality of the openings for the trench.

8. The method according to claim 1, further comprising:
repeating a process of forming a pattern layer by removing a part of a resin layer with laser irradiation to form a plurality of pattern layers, each of the pattern layers having a pattern including an opening for the wiring and an opening for the trench, the plurality of the pattern layers forming a plurality of openings for the trench; and
repeating a process of forming a conductor layer comprising a via portion that fills the opening for the wiring to form a plurality of conductor layers, wherein
the insulating resin layer of the redistribution layer is formed by the plurality of the pattern layers,
the wiring of the redistribution layer is formed by the plurality of the conductor layers, and
the trench is formed by connecting the plurality of the openings for the trench.

9. The method according to claim 1, further comprising:
repeating a process of forming a pattern layer through exposure and development of a photosensitive resin layer to form a plurality of pattern layers, each of the pattern layers having a pattern including an opening for the wiring; and
repeating a process of forming a conductor layer comprising a via portion that fills the opening for the wiring to form a plurality of conductor layers, wherein
the insulating resin layer of the redistribution layer is formed by the plurality of the pattern layers,
the wiring of the redistribution layer is formed by the plurality of the conductor layers, and
a part of the formed insulating resin layer is removed with laser irradiation to form the trench.

10. The method according to claim 1, wherein the trench has a width increasing in a direction away from the base material.

11. The method according to claim 1, further comprising: mounting the wiring structure on an organic wiring substrate.
